(19) United States
(12) Patent Application Publication
(10) Pub. No.: US 2005/0265487 A1
(43) Pub. Date: Dec. 1, 2005

(54) Method of sampling data and a circuit for sampling data

(75) Inventor: Antony Sou, Manchester (GB)

Correspondence Address: PILLSBURY WINTHROP SHAW PITTMAN, LLP, P.O. BOX 10500, MCLEAN, VA, 22102, US

(73) Assignee: XYRATEX TECHNOLOGY LIMITED, Hampshire (GB)

(21) Appl. No.: 11/138,325

(22) Filed: May 27, 2005

Related U.S. Application Data
(60) Provisional application No. 60/574,673, filed on May 27, 2004.

(51) Int. Cl. H03D 3/24

(52) U.S. Cl. 375/326; 375/355

(57) ABSTRACT

The present invention relates to a method of sampling a received digital data stream. The method comprises: generating a first sampling clock in dependence on a detected rate of said received digital data stream for sampling at a first time within a bit period of said received digital data stream; detecting a shape of a data eye of data within said received digital data stream; and generating a second sampling clock interleaved with said first sampling clock for sampling at a second different time within a bit period the second sampling clock being offset from said first sampling clock by an amount dependent on the detected shape of the data eye.

The present invention relates to a method and a circuit for sampling digital data.

Conventionally, when a digital data stream is received at a receiver, a clock signal is recovered from the received data stream to enable accurate sampling of the data stream. This is usually achieved by determining a location of a transition of the data (e.g. from high to low). The data stream at this location is sampled at the receiver by what is commonly referred to as the Q sample. The Q sample is taken at a time within a bit period corresponding to a generated Q sampling clock signal.

From the calculated timing of the Q sample, i.e. the location of the Q sample within a bit period, together with knowledge of the frequency of the data, an estimation is made as to a suitable position for a sample of the data to be taken, referred to as the I sample. The I sample is taken at a time corresponding to a determined I sampling clock. Typically there is a presumption that the timing of the I sample within the bit period should be half a bit period from the position of the Q sample. QB and IB samples are also generated a whole bit period ahead of the Q and I samples, respectively.

The presumption that the I sample and Q sample within each bit period are spaced apart in time by exactly half a bit period is itself based on a presumption that a data eye of the data stream is entirely symmetrical. In other words the presumption is that the position of the data maximum will necessarily lie half way between two consecutive data transitions. This is not necessarily the case.

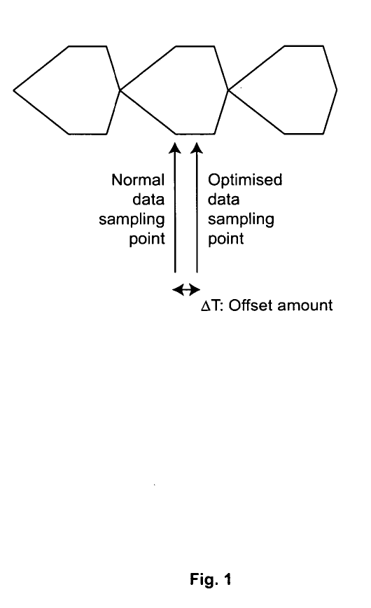

FIG. 1 shows a schematic representation of a data eye of a typical digital data stream received from a network. Referring to FIG. 1, it can be seen that the shape of the data eye is not symmetrical over time. Accordingly the position of the data transition and the shape of the data eye is such that if a presumption is made that at all times the I sample should be made at exactly half a bit period from the time at which the Q sample is made, errors in data detection will be made. This can increase a bit error rate for data received from the network, which is clearly undesirable.

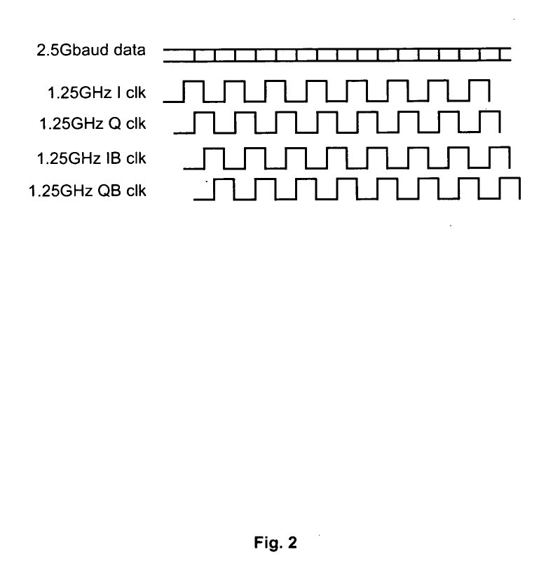

FIG. 2 shows four sampling clock signals having different equally spaced phases for sampling a 2.5 Gbaud serial data stream. During each sampling cycle, two data bits and two data transitions are sampled. In this design, the data bits are sampled by the rising edges of the I clock and IB clock and the data transitions are sampled by the rising edges of the Q clock and QB clock. There is a fixed 90-degree phase relationship between these sampling clocks and accordingly, as explained above, such an arrangement of sampling clocks may introduce significant increases in the bit error rate when the data eyes of bits within a received serial data stream are not symmetrical.

Attempts have been made to address this problem. One such attempt is described in U.S. patent application No. US-A-2002/0067787. In this document, there is disclosed a method of data recovery in which the timing of the I sample is varied by selection of one of a plurality of predetermined sampling times. In other words, instead of separating the Q and I samples by exactly half a bit period, some variation in the separations is enabled. However, the architecture and method suggested in this document introduces considerable complexity into the circuit design for a data recovery circuit. In particular, means for generating each of a plurality of possible sampling clocks at many different times during a bit period is required. This is undesirable.

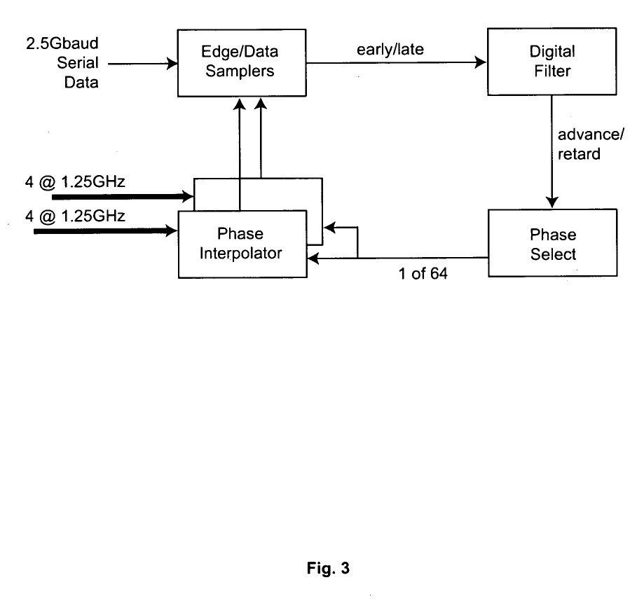

FIG. 3 shows an example of the architecture of a known clock recovery circuit that may be used to define the sampling times of a received digital data stream. In this example, a serial data stream is received and filtered. An advance/retard signal is determined based on an output from the digital filter. The advance/retard signal is provided to a phase select function that operates to move the position of the sampling clocks used. This is achieved by two-phase interpolators arranged to select proportions of predetermined phase signals to generate the sampling clocks.

The relative separation of the Q and I sampling clocks generated by this circuit is fixed such that at all times, the I sampling clock is exactly half a bit period from the Q sampling clock. Accordingly, as explained above, where the data eye of a received digital data stream is not symmetrical (see the example in FIG. 1), this can lead to an increase in the bit error rate.

According to a first aspect of the present invention there is provided a method of sampling a received digital data stream, the method comprising: generating a first sampling clock in dependence on a detected rate of said received digital data stream for sampling at a first time within a bit period of said received digital data stream; detecting a shape of a data eye of data within said received digital data stream; and generating a second sampling clock interleaved with said first sampling clock for sampling at a second different time within a bit period the second sampling clock being offset from said first sampling clock by an amount dependent on the detected shape of the data eye.

The invention provides a method by which a second sampling clock may be generated offset from the first sampling clock in dependence on a detected shape of the data eye of a received data stream. The offset may be selected so that the second sampling clock substantially coincides with an expected position of a data signal of the received digital data stream.

According to a second aspect of the present invention there is provided a circuit for sampling a digital data stream, the circuit comprising: a data receiver for receiving the digital data stream; a detector for detecting a phase and frequency of the digital data stream and for detecting a shape of a data eye of said received digital data stream; and a sampling clock generator for generating first and second data sampling clocks offset from each other by an amount dependent on the detected shape of the data eye.

Examples of the present invention will now be described in detail with reference to the accompanying drawings, in which:

FIG. 1 shows an example of a serial data stream that may be received at a data recovery circuit;

FIG. 2 shows an example of clock signals used to define the position of sampling of a received data stream;

FIG. 3 shows an example of architecture of a known clock recovery circuit;

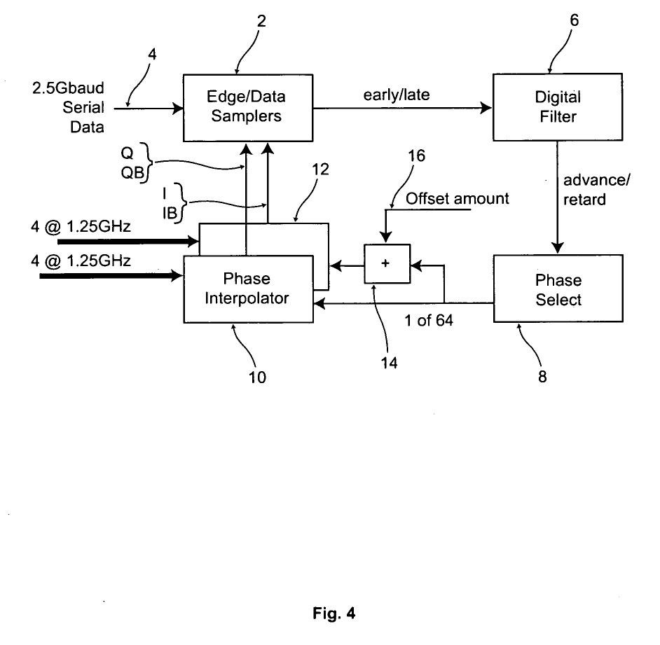

FIG. 4 shows a schematic representation of the architecture of an example of a data recovery circuit according to an embodiment of the present invention.

Referring to FIG. 4, the architecture of an example of a circuit for sampling data according to an embodiment of the present invention, is shown. The data sampling circuit comprises an edge/data sampler unit 2 arranged to receive a serial stream of data 4 from a source such as a network (not shown). In the example shown, the unit 2 functions to generate four sampling clocks to sample both edges (transitions) and data within the received data stream. Q and QB sampling clocks are used to sample the edges and I and IB sampling clocks are used to sample data. The I and IB sampling clocks are interleaved with the Q and QB sampling clocks, in that in time the rising edges of the sampling clocks occur in sequence, i.e. within a two bit period the rising edges of the sampling clocks are encountered in the following order: I, Q, IB, QB.

The unit 2 detects the phase of the received data stream and provides an early/late signal to a digital filter 6 arranged in communication with a phase select unit 8. In turn the phase select unit 8 is able to control a number of phase interpolators (to be described in more detail below) to adjust the phases of the Q, QB, I and IB sampling clocks.

In the example shown, two phase interpolators 10 and 12 are provided in communication with the phase select unit 8. The phase select unit 8 is arranged to provide signals to each of the two phase interpolators 10 and 12. An offset addition unit 14 is provided arranged to receive an input 16. In the example shown, the phase interpolators 10 and 12 each receive as inputs four signals of different phases similar to those shown schematically in FIG. 3. The four signals are preferably provided by a signal generator such as a phase locked loop or a delay locked loop.

The phase interpolators 10 and 12 are operative to select two of the four signals and generate a weighted sum of the selected two signals so that sampling clocks can be created by each of the phase interpolators having a phase somewhere between the two selected signals. Phase interpolators of this type are known. See, for example U.S. Pat. No. 6,002,279, the entire contents of which are hereby incorporated by reference.

In use, phase interpolator 10 is typically used to generate the Q and QB sampling clocks. These are used to sample the transition of data within the serial data stream 4. The I and IB sampling clocks are generated by the phase interpolator 12. Conventionally, these would be spaced from the Q and QB sampling clocks by exactly half a bit period. This is based on the presumption that at a time half a bit period from the time of the (rising edges of the) Q and QB sampling clocks, an accurate reading of the data can be made.

As explained above, due to the nature of the data eye of data within the serial data stream 4 in some cases this will lead to errors. To address this, in the example shown an offset 16 is provided to the phase interpolator 12 used to generate the I and IB sampling clocks. Referring to FIG. 1, the offset may be such that the sampling point of the data is moved from the normal data sampling point to an optimised data sampling point where the chance of obtaining a true reading is increased. Since in the example shown in FIG. 4 there are two phase interpolators, one to produce the I and IB sampling clocks and the other to produce the Q and QB sampling clocks, a different phase position (offset) may be applied to the data sampling clocks.

This enables the transition sampling clocks (Q and QB) and the data sampling clocks (I and IB) to be moved relative to each other. Each of the phase interpolators 10 and 12 functions to provide an output made up of a weighted combination of two of the four clock signals it receives as inputs so that between them the two phase interpolators are able to produce the I, IB, Q and QB sampling clocks at the desired positions.

The offset provided to the phase interpolator 12 is preferably user-programmable. In this case, the offset 16 can be chosen by a user to suit the particular shape of the data eye in the data stream. The offset may be varied as the shape of the data eye in the data stream changes over time. This may be achieved automatically with the use of a scanning circuit arranged to step through a data eye and take samples through a data eye to determine the shape of the data eye. Information obtained from the scanning may then be processed to determine a suitable location of the sampling clocks with respect to each other.

Alternatively, if appropriate, the offset may be fixed at a constant value by the user. In a further example a calibration or training cycle is performed prior to normal data recovery. In this case a calibration or training cycle is provided by another circuit and enables a user or an automatic detection circuit to determine the shape of the data eye prior to normal data recovery so that suitable location of the sampling clocks may be determined for the normal data recovery.

In another example, two phase select units 8 are provided, a first being arranged to provide a signal to phase interpolator 10 and a second being used to provide a signal to the phase interpolator 12. The second phase selector calculates a new data sampling position from the advance/retard signals obtained from the digital filter 6.

It can be seen that in embodiments of the present invention, in contrast to conventional clock recovery circuits either in which the data sampling clock is positioned such that there is always a fixed relationship between the Q and I sampling clocks or in which a plurality of phase signals are generated, the present invention provides a simple and robust method and apparatus by which data in a serial data stream may be sampled whilst minimising the bit error rate.

Embodiments of the present invention have been described with particular reference to the examples illustrated. However, it will be appreciated that variations and modifications may be made to the examples described within the scope of the present invention.

1. A method of sampling a received digital data stream, the method comprising:
generating a first sampling clock independence on a detected rate of said received digital data stream for sampling at a first time within a bit period of said received digital data stream;
detecting a shape of a data eye of data within said received digital data stream; and
generating a second sampling clock interleaved with said first sampling clock for sampling at a second different time within a bit period the second sampling clock being offset from said first sampling clock by an amount dependent on the detected shape of the data eye.

2. A method according to claim 1, in which generating the second sampling clock comprises, receiving an offset and generating the second sampling clock at a time period away from said first sampling clock, the time period consisting substantially of half a bit period of the received data stream plus the received offset.

3. A method according to claim 1, in which the first and second sampling clocks are generated using a phase interpolator.

4. A method according to claim 3, comprising providing as an input to the phase interpolator an adjustment signal obtained from the received digital data stream, the adjustment signal relating to the phase of both the first and second sampling clocks and an offset, the offset being selected to determine the time period between the first and second sampling clocks.

5. A method according to claim 4, in which the first sampling clock is used to sample data transitions within the data stream and the second sampling clock is used to sample data signals of the received digital data stream.

6. A method according to claim 1, comprising generating the first sampling clock using a first phase interpolator, and generating the second sampling clock using a second phase interpolator.

7. A method according to claim 6, comprising receiving the offset at the first or second phase interpolator.

8. A method according to claim 1, comprising detecting the shape of a data eye of said received digital data stream and adjusting the offset in dependence thereon.

9. A circuit for sampling a digital data stream, the circuit comprising:
a data receiver for receiving the digital data stream;
a detector for detecting a phase and frequency of the digital data stream and for detecting a shape of a data eye of said received digital data stream; and
a sampling clock generator for generating first and second data sampling clocks offset from each other by an amount dependent on the detected shape of the data eye.

10. A circuit according to claim 9, comprising a phase selector arranged to receive a signal from the data receiver indicative of whether the phases of first and second sampling clocks need to be moved.

11. A circuit according to claim 10, comprising a phase interpolator arranged to receive a plurality of phase component signals and to receive an input from the phase selector to enable generation of a weighted sum of two or more of the phase component signals.

12. A circuit according to claim 11, comprising a respective phase selector and phase interpolator to generate each of the sampling clocks.

13. A circuit according to claim 12, comprising an offset generator for providing to at least one of the phase interpolators an offset signal such that the sampling clock generated by that phase interpolator is offset with respect to the sampling clock generated by the other phase interpolator.
